(19) United States
(12) Patent Application Publication
(10) Pub. No.: US 2022/0413864 A1
(43) Pub. Date: Dec. 29, 2022

(54) RUN-LENGTH ENCODING AND DECODING FOR A WAVEFORM

(71) Applicant: International Business Machines Corporation, Armonk, NY (US)

(72) Inventors: Timothy Lindquist, Rochester, MN (US); George Russell Zettles, IV, Rochester, MN (US); Jarrett Betke, Hoffman Estates, IL (US); Daniel Ramirez, Rochester, MN (US); George Paulik, Rochester, MN (US)

(21) Appl. No.: 17/355,767

(22) Filed: Jun. 23, 2021

(51) Int. Cl. G06F 9/30; G06F 9/50

(52) U.S. Cl. CPC G06F 9/30196; G06F 9/5061; G06F 9/30149; G06F 9/30098

(57) ABSTRACT

Systems, computer-implemented methods and/or computer program products are provided for facilitating waveform synthesis. A system can comprise a memory that stores computer executable components and a processor that executes the computer executable components stored in the memory. The computer executable components can comprise a composing component that compresses data defining a waveform by employing amplitude partitioning of the data using equivalent sizing. The composing component can further employ run-length encoding to generate a string of integers representing a plurality of groups of the data as partitioned according both to amplitude and progressing time. In an embodiment, a decoding component can employ a binary search to decode a running sum array of integers representing at least a portion of the data, to decompress the data.

### BACKGROUND

One or more embodiments described herein relate generally to waveform synthesis, and more specifically, to run-length encoding and decoding for a waveform.

### SUMMARY

The following presents a summary to provide a basic understanding of one or more embodiments described herein. This summary is not intended to identify key or critical elements, or to delineate any scope of the particular embodiments and/or any scope of the claims. The sole purpose of the summary is to present concepts in a simplified form as a prelude to the more detailed description that is presented later. In one or more embodiments described herein, devices, systems, computer-implemented methods, apparatuses and/or computer program products are described that can facilitate waveform synthesis, such as including run-length encoding and/or decoding.

According to an embodiment, a system can comprise a memory that stores computer executable components and a processor that executes the computer executable components stored in the memory. The computer executable components can comprise a composing component that compresses data defining a waveform by employing amplitude partitioning of the data using equivalent sizing.

According to another embodiment, a computer-implemented method can comprise compressing, by a system operatively coupled to a processor, data defining a waveform by employing amplitude partitioning of the data using equivalent sizing.

According to still another embodiment, a computer program product for facilitating waveform synthesis can comprise a computer readable storage medium having program instructions embodied therewith. The program instructions can be executable by a processor to compress, by the processor, data defining a waveform by employing amplitude partitioning of the data using equivalent sizing.

### DESCRIPTION OF THE DRAWINGS

FIG. 1 illustrates a block diagram of an example, non-limiting system that can facilitate waveform synthesis, in accordance with one or more embodiments described herein.

FIG. 2 illustrates another block diagram of an example, non-limiting system that can facilitate waveform synthesis, in accordance with one or more embodiments described herein.

FIG. 3 illustrates a graph of a periodic waveform scaled over varying frequencies. The base periodic waveform can be synthesized, in accordance with one or more embodiments described herein.

FIG. 4 illustrates a graph of a sinusoid waveform that can be synthesized, in accordance with one or more embodiments described herein. FIG. 4 also illustrates a graph of a quarter wave of the sinusoid waveform, having been at least partially synthesized, in accordance with one or more embodiments described herein.

FIG. 5 illustrates a graph of a full wave of the sinusoid waveform of FIG. 4, having been at least partially synthesized, in accordance with one or more embodiments described herein.

FIG. 6 illustrates a flow diagram of an example, non-limiting computer-implemented method that can facilitate waveform synthesis, in accordance with one or more embodiments described herein.

FIG. 7 illustrates a continuation of the flow diagram of FIG. 6, of an example, non-limiting computer-implemented method that can facilitate waveform synthesis, in accordance with one or more embodiments described herein.

FIG. 8 illustrates another continuation of the flow diagram of FIG. 6, of an example, non-limiting computer-implemented method that can facilitate waveform synthesis, in accordance with one or more embodiments described herein.

FIG. 9 illustrates a block diagram of an example, non-limiting operating environment in which one or more embodiments described herein can be facilitated.

FIG. 10 illustrates a block diagram of an example, non-limiting cloud computing environment in accordance with one or more embodiments described herein.

FIG. 11 illustrates a block diagram of a plurality of example, non-limiting abstraction model layers, in accordance with one or more embodiments described herein.

### DETAILED DESCRIPTION

The following detailed description is merely illustrative and is not intended to limit embodiments, application and/or uses of embodiments. Furthermore, there is no intention to be bound by any expressed and/or implied information presented in the preceding Background and/or Summary sections, and/or in this Detailed Description section.

Quantum computing generally involves the use of quantum-mechanical phenomena to perform computing and information processing functions. Quantum computing can employ quantum physics to encode and process information rather than binary digital techniques based on transistors. That is, while classical computers can operate on bit values that are either 0 or 1, a quantum computing device can employ quantum bits (also referred to as qubits) that can operate according to the laws of quantum physics and can exhibit phenomena such as superposition and/or entanglement.

The superposition principle of quantum physics can allow a qubit to be in a state that partially represents both a value of “1” and a value of “0” at the same time. The entanglement principle of quantum physics can allow qubits to be correlated. For instance, a state of a first qubit can depend on a state of a second qubit, and/or vice versa. As such, a quantum circuit can employ qubits to encode and process information in a manner that can be quite different from binary digital techniques based on transistors. Indeed, quantum computing has the potential to solve problems that, due to computational complexity, cannot be solved or can only be solved comparatively more slowly on a classical computer.

Quantum computing can utilize specialized controls, such as quantum circuits, to operate on qubits. Quantum circuits are transformations that can perform operations on qubits. Quantum circuits, for instance as part of a quantum program, can be implemented as one or more quantum gates, such as a sequence of quantum gates. The quantum gates can be implemented as one or more physical operations on a set of qubits, such as implementing a sequence of pulses. A pulse is a time-dependent tone (e.g., wave or waveform) that can be applied to a qubit to change a state of the qubit and/or to measure a state of the qubit.

Quantum programming can involve the process of assembling sequences of instructions, which can be called quantum programs, that can be capable of running on a quantum computer. A quantum program can be associated with a collection of quantum circuits. When a quantum program is executed, one or more measurements can be computed, such as by the quantum system and/or associated classical system. The one or more measurements can include one or more resonant and/or oscillating frequencies of one or more qubits of the quantum system, which one or more resonant and/or oscillating frequencies can represent one or more states and/or oscillations of the one or more qubits.

One method of measuring a resonant frequency can be to operate on one or more qubits with a signal generated by a signal generator. A base waveform for the signal can be stepped through various frequencies to operate a plurality of voltages on the one or more qubits, such as via a frequency modulation approach. Stepping through the frequencies can produce one or more signals over a desired range of frequencies. Generation of the base waveform can be facilitated by one or more suitable components, such as a hardware network analyzer (HNA) and/or field programmable gate array (FPGA), such as based on digital direct synthesis (DDS). Generally, DDS is a method of generating an analog waveform by synthesizing a time-varying signal in a digital form. A digital to analog conversion can be performed to convert the digital form to an analog form.

One or more embodiments as described herein can provide one or more systems, methods and/or computer program products to generate high-fidelity signals employing low amounts of memory, time and/or computing power. To provide the signals, the described subject matter can employ various techniques that can provide a dynamic approach to waveform synthesis, such as including encoding, decoding and/or storage of a waveform. The approach can be dynamic because the approach can account for waveforms having various shapes, amplitudes, frequencies and/or symmetries.

Relative to quantum operations, the waveform can be employed to generate one or more signals, such as to operate on one or more qubits. With respect to quantum applications, the various waveform synthesis techniques described herein can be applicable in the quantum fields of teleportation, measurement-based computation and/or error correction.

Likewise, the various waveform synthesis techniques described herein also can be applicable for non-qubit operations. For example, the described subject matter can be applicable to waveform synthesis relative to a filter system such as a filtering circuit. That is, it will be appreciated that the described subject matter can be applicable to waveform synthesis for classical and/or quantum systems.

The described subject matter can, in one or more embodiments, improve (e.g., enhance and/or optimize) the execution time of and/or quality for waveform synthesis, and thus also for performing qubit state and/or oscillation frequency measurement relative to one or more quantum jobs. In one or more cases, one or more embodiments described herein can allow for increased scaling of execution of one or more jobs, such as quantum jobs, in view of increased execution time and/or execution quality. Additionally and/or alternatively, employing the described subject matter can allow for reduced cost and/or complexity of a system employed to utilize a waveform synthesized according to the described subject matter. This allowance can be due at least to the employment of low amounts of memory, time and/or computing power for encoding, decoding and/or storage the waveform, as enabled by waveform synthesis in accordance with the described subject matter.

One or more of the aforementioned embodiments are now described with reference to the figures, where like referenced numerals are used to refer to like elements throughout. In the following description, for purposes of explanation, numerous specific details are set forth in order to provide a more thorough understanding of the one or more embodiments. It is evident in one or more cases, however, that the one or more embodiments can be practiced without these specific details.

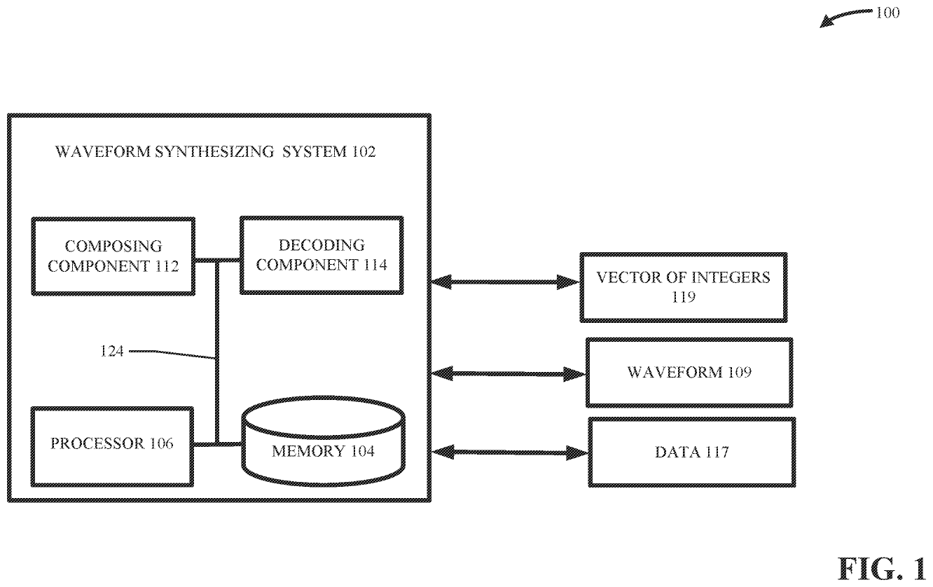

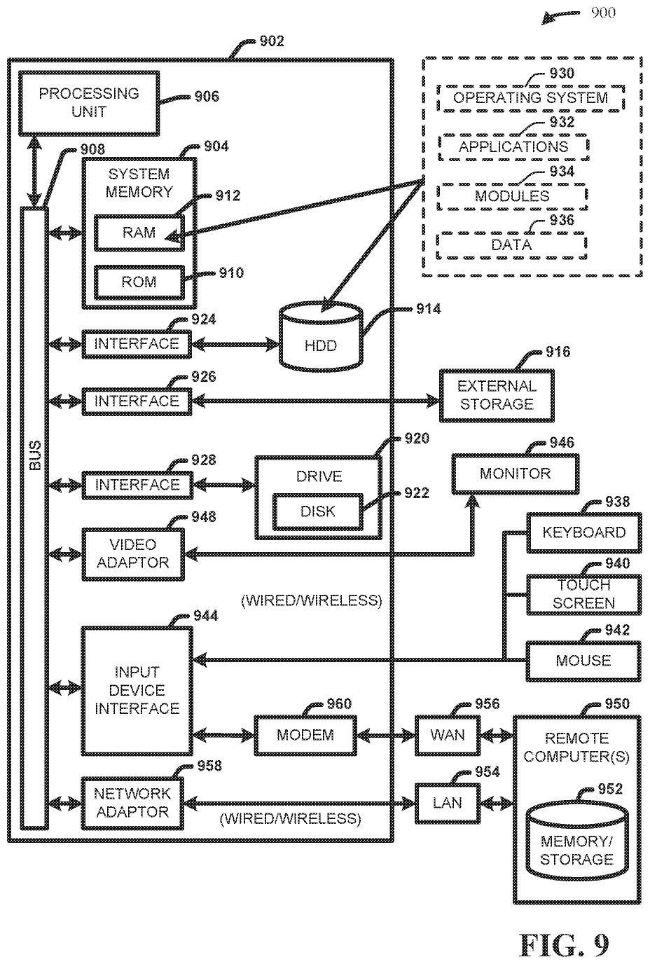

Further, it will be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein. For example, in one or more embodiments, the non-limiting systems 100 and/or 200 as illustrated at FIGS. 1 and/or 2, and/or systems thereof, can further comprise one or more computer and/or computing-based elements described herein with reference to an operating environment, such as the operating environment 900 illustrated at FIG. 9. In one or more described embodiments, computer and/or computing-based elements can be used in connection with implementing one or more of the systems, devices, components and/or computer-implemented operations shown and/or described in connection with FIGS. 1 and/or 2 and/or with other figures described herein.

Turning first to FIG. 1, one or more embodiments described herein can include one or more systems, computer-implemented methods, apparatuses and/or computer program products that can facilitate waveform synthesis, such as including compression of data representing the waveform. For example, FIG. 1 illustrates a block diagram of an example, non-limiting system 100 that can facilitate waveform synthesis relative to one or more waveforms and/or one or more data set representing a waveform having varying shapes, amplitudes, frequencies and/or symmetries. Such waveforms can include, but are not limited to, periodic waveforms and/or waveforms having even and/or odd symmetry. Further, the waveform and/or data synthesized can include and/or represent one or more periods and/or waveform portions.

As illustrated, the non-limiting system 100 can comprise a waveform synthesizing system 102. The waveform synthesizing system 102 can include for example, one or more suitable devices including computing device(s) that can enable waveform encoding, decoding and/or storage. As used herein, the one or more computing device(s) can be and/or can include one or more of a general-purpose computer, a special-purpose computer, a quantum computing device (e.g., a quantum computer), a tablet computing device, a handheld device, a server class computing machine and/or database, a laptop computer, a notebook computer, a desktop computer, a cell phone, a smart phone, a consumer appliance and/or instrumentation, an industrial and/or commercial device, a digital assistant, a multimedia Internet-enabled phone and/or another type of device. In one or more embodiments, the waveform synthesizing system 102 can be associated with, such as accessible via, a cloud computing environment.

The waveform synthesizing system 102 can comprise one or more components, such as a memory 104, processor 106, bus 124, composing component 112 and/or decoding component 114. Generally, waveform synthesizing system 102, and thus non-limiting system 100, can facilitate waveform synthesis of a waveform 109 and/or of data 117 defining the waveform 109.

The composing component 112 generally can compress the data 117 defining the waveform 109 by employing amplitude partitioning of the data 117 using equivalent sizing. The composing component 112 can thus function to partition the data 117 into a plurality of groups having equal changes in (A) amplitudes. That is, the composing component 112 can partition the data 117 into a plurality of groups, also referred to herein as bins, representing the waveform 109. Additionally, the bins can be generated according to equal amplitude partitioning of the waveform 109, for example along an amplitude direction of the waveform 109.

In view of this equal partitioning, the composing component 112 can further partition the data 117 employing time partitioning of the data 117 using varying sizing. The composing component 112 can thus function to partition the data 117 into the plurality of groups further having varying changes in (A) progressing time values that correlate to the equal A amplitudes of the waveform 109. That is, the bins can be generated according to varying time partitioning of the waveform 109, for example along a time direction of the data.

Accordingly, the composing component 112 generally can partition the data 117 defining the waveform 109 into a plurality of successively progressing, time-partitioned sections of the data 117, and thereby also can partition the waveform 109 into a plurality of successively progressing, time-partitioned sections of the waveform 109. As typically pictorially graphed, the amplitude direction of a waveform typically is directed along a y-axis of a graph. Likewise, it also will be appreciated that as typically pictorially graphed, the time direction of a waveform typically is directed along an x-axis of the graph.

It will be appreciated that the aforementioned partitioning can allow for additional operations that can generate a string and/or vector of integers 119 representing the plurality of groups of the data 117 as partitioned according both to amplitude and progressing time. That is, the data 117 defining the waveform 109 can be compressed into a string and/or vector of integers 119 that can employ low amounts of memory, time and/or computing power for encoding, decoding and/or storing the data, and thus for encoding, decoding and/or storing the waveform 109. This can particularly be the case as compared to the amounts of memory, time and/or computing power for existing encoding, decoding and/or storage techniques related to waveforms and/or data defining waveforms.

In summary, the waveform synthesizing system 102 can process, such as synthesize, waveforms having variable shapes, amplitudes, frequencies and/or symmetries. Likewise, the one or more processes to be performed by the waveform synthesizing system 102 can be employed to generate a high-fidelity signal as compared to existing approaches for signal generation. Accordingly, one or more processes to be performed by the waveform synthesizing system 102 can provide waveform synthesis that can improve (e.g., enhance and/or optimize) the execution time of, and/or quality for, waveform synthesis. The one or more processes also can thus improve (e.g., enhance and/or optimize) the execution time of, and/or quality for, performing qubit state and/or oscillation frequency measurement relative to one or more quantum jobs.

Further, the low memory, time and/or computing power employed for encoding, decoding and/or storing the waveform 109 and/or data 117 can be much lower than comparatively employed by existing waveform synthesis techniques and/or approaches. As such, employing the described subject matter can allow for reduced cost and/or complexity of a system employed to utilize a waveform that has been synthesized according to the described subject matter. It also follows that one or more embodiments described herein can allow for increased scaling of execution of one or more jobs, such as quantum jobs, in view of increased execution time and/or execution quality.

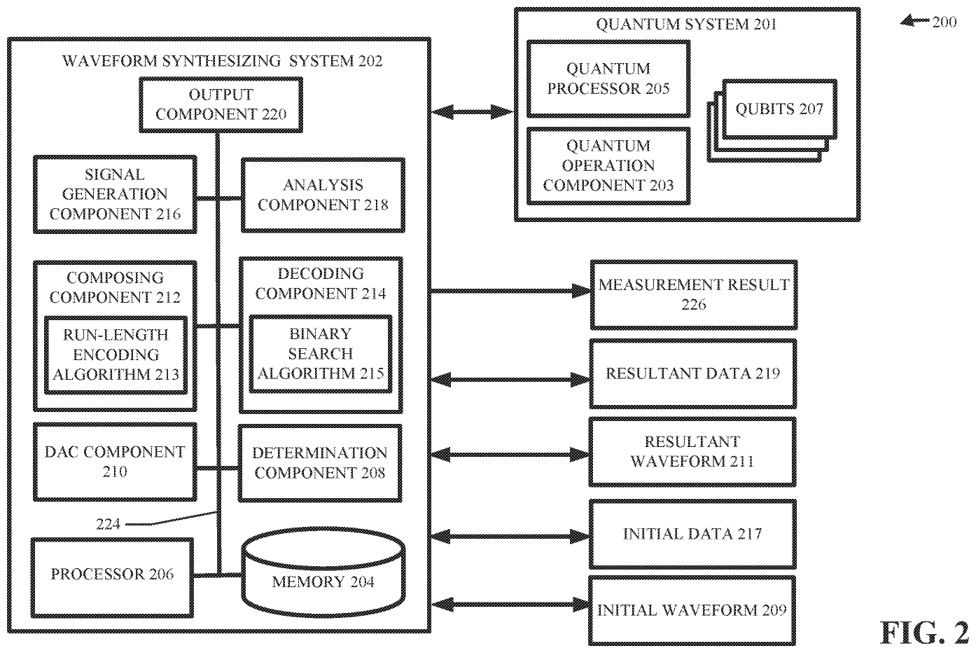

Turning next to FIG. 2, the figure illustrates a block diagram of an example, non-limiting system 200 that can facilitate waveform synthesis in accordance with one or more embodiments described herein. It will be appreciated that descriptions regarding the non-limiting system 100 and/or one or more components thereof can apply to the non-limiting system 200 and/or to one or more components thereof and/or vice versa.

It further will be appreciated that the following description(s) refer(s) to the operation of waveform synthesis performed relative to a single waveform and/or set of data defining a single waveform. However, one or more of the processes described herein can be scalable. For example, as will be appreciated below, the waveform synthesizing system 202 can perform at least one waveform synthesis at least partially in parallel at a same time with another waveform synthesis. This parallel performance can include one or more encoding and/or decoding processes performed at least partially in parallel at a same time with one or more other encoding and/or decoding processes. The resulting performance scalability can be provided at least in part due to the use of run-length encoding processes and/or of a running sum index array to encode, decode and/or store a waveform and/or data defining a waveform. In view thereof, the waveform synthesizing system 202 can employ a low amount of system memory, computing power and/or computation time for the respective encoding, decoding and/or storage.

Turning now to one or more details of the non-limiting system 200, as illustrated, the non-limiting system 200 can comprise a quantum system 201 and a classical system, such as a waveform synthesizing system 202. In one or more embodiments, the non-limiting system 200 can be a hybrid system. In such example, the quantum system 201 can be separate from, but function in combination with, the non-limiting system 200.

The illustrated quantum system 201 (e.g., quantum computer system, superconducting quantum computer system and/or the like) can employ quantum algorithms and/or quantum circuitry, including computing components and/or devices, to perform quantum operations and/or functions on input data to produce results that can be output to an entity. As user herein, the term “entity” can refer to a device, smart device, component, hardware, software and/or human.

The quantum circuitry can comprise circuitry for quantum bits (qubits), such as multi-bit qubits, physical circuit level components, high level components and/or functions. The quantum circuitry can involve physical pulses that can be structured (e.g., arranged and/or designed) to perform desired quantum functions and/or computations on data (e.g., input data and/or intermediate data derived from input data) to produce one or more quantum results and/or measurements as an output. The quantum results and/or measurements can be responsive to the quantum job request and associated input data and can be based at least in part on the input data (e.g., an input waveform and/or signal), quantum functions and/or quantum computations.

In one or more embodiments, the quantum system 201 can comprise one or more quantum components, such as a quantum operation component 203 and/or a quantum processor 205. The quantum operation component 203 can perform one or more quantum processes, calculations and/or measurements for operating one or more quantum circuits on one or more qubits 207. For example, the quantum operation component 203 can operate one or more qubit effectors, such as qubit oscillators, harmonic oscillators, pulse generators and/or the like to cause one or more pulses and/or signals to stimulate and/or manipulate the state(s) of the one or more qubits 207 existing at the quantum system 201. Additionally and/or alternatively, the quantum operation component 203 can perform one or more measurements employing one or more digital waveforms 209 and/or analog waveforms 211.

The quantum processor 205 can be a suitable processor, such as being capable of controlling qubit generation and the like. The quantum processor 205 can generate one or more instructions for controlling the one or more processes of the quantum operation component 203.

Turning now to the classical portion of the non-limiting system 200, the waveform synthesizing system 202 can comprise a type of component, machine, device, facility, apparatus and/or instrument that comprises a processor and/or can be capable of effective and/or operative communication with a wired and/or wireless network. All such embodiments are envisioned. For example, waveform synthesizing system 202 can comprise a server device, computing device, general-purpose computer, special-purpose computer, quantum computing device (e.g., a quantum computer), tablet computing device, handheld device, server class computing machine and/or database, laptop computer, notebook computer, desktop computer, cell phone, smart phone, consumer appliance and/or instrumentation, industrial and/or commercial device, digital assistant, multimedia Internet enabled phone, multimedia players and/or another type of device and/or computing device.

In one or more embodiments, waveform synthesizing system 202 can comprise a processor 206 (e.g., computer processing unit, microprocessor, classical processor, quantum processor and/or like processor). In one or more embodiments, a component associated with waveform synthesizing system 202, as described herein with or without reference to the one or more figures of the one or more embodiments, can comprise one or more computer and/or machine readable, writable and/or executable components and/or instructions that can be executed by processor 206 to facilitate performance of one or more processes defined by such component(s) and/or instruction(s). In one or more embodiments, the processor 206 can comprise a determination component 208, digital to analog conversion component 210, composing component 212, decoding component 214, signal generation component 216, analysis component 218 and/or output component 220.

In one or more embodiments, the waveform synthesizing system 202 can comprise a computer-readable memory 204 that can be operably connected to the processor 206. The memory 204 can store computer-executable instructions that, upon execution by the processor 206, can cause the processor 206 and/or other components of the waveform synthesizing system 202 (e.g., determination component 208, digital to analog conversion component 210, composing component 212, decoding component 214, signal generation component 216, analysis component 218 and/or output component 220) to perform one or more actions. In one or more embodiments, the memory 204 can store computer-executable components (e.g., determination component 208, digital to analog conversion component 210, composing component 212, decoding component 214, signal generation component 216, analysis component 218 and/or output component 220).

Waveform synthesizing system 202 and/or a component thereof as described herein, can be communicatively, electrically, operatively, optically and/or otherwise coupled to one another via a bus 224 to perform functions of non-limiting system 200, waveform synthesizing system 202 and/or one or more components thereof and/or coupled therewith. Bus 224 can comprise one or more of a memory bus, memory controller, peripheral bus, external bus, local bus, quantum bus and/or another type of bus that can employ one or more bus architectures. One or more of these examples of bus 224 can be employed to implement one or more embodiments described herein.

In one or more embodiments, waveform synthesizing system 202 can be coupled (e.g., communicatively, electrically, operatively, optically and/or like function) to one or more external systems, sources and/or devices (e.g., classical and/or quantum computing devices, communication devices and/or like devices), such as via a network. In one or more embodiments, one or more of the components of the non-limiting system 200 can reside in the cloud, and/or can reside locally in a local computing environment (e.g., at a desired location(s)).

In addition to the processor 206 and/or memory 204 described above, waveform synthesizing system 202 can comprise one or more computer and/or machine readable, writable and/or executable components and/or instructions that, when executed by processor 206, can facilitate performance of one or more operations defined by such component(s) and/or instruction(s). Further, in one or more embodiments, waveform synthesizing system 202 can comprise the determination component 208, digital to analog conversion component 210, composing component 212, decoding component 214, signal generation component 216, analysis component 218 and/or output component 220.

Turning now to the determination component 208, an initial waveform 209, such as a digital waveform, and/or initial data 217 defining the initial waveform 209, such as digital data, can be obtained by the determination component 208. The initial waveform 209 can be and/or the initial data 217 can define a waveform having a variable shape, amplitude, frequency and/or symmetry. Such waveform can include, but is not limited to, periodic waveforms and/or a waveform having even and/or odd symmetry. The initial waveform 209 and/or initial data 217 synthesized can include and/or represent one or more periods and/or waveform portions. Further, one or more additional process can be performed by the waveform synthesizing system 202 to further lower one or more of memory, computing power and/or time employed with respect to synthesis of the initial waveform 209 and/or initial data 217. This can be the case where the initial waveform 209 is a periodic waveform and/or a waveform having even and/or odd symmetry, such as a sinusoid waveform having even and odd symmetry.

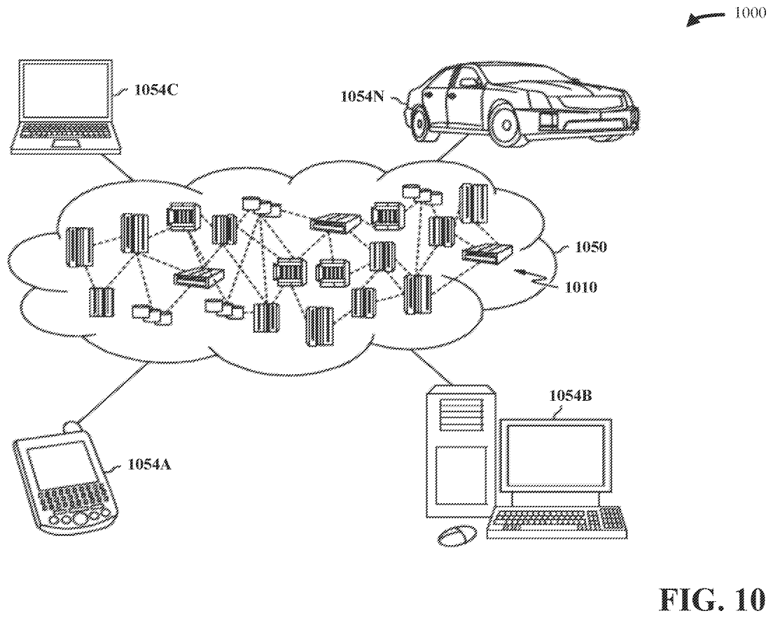

The determination component 208 can employ one or more aspects of an operating environment, such as the operating environment 900 illustrated at FIG. 9, to provide, such as to receive, retrieve and/or otherwise obtain, the initial waveform 209 and/or the initial data 217. By way of a non-limiting example, the initial waveform 209 and/or initial data 217 can be downloaded directly and/or indirectly from the quantum operation component 203 and/or from the waveform synthesizing system 202, received from the memory/storage 952 via the WAN 956, and/or downloaded via the WAN 956 from a node, such as a cloud computing node 1010 of a cloud computing environment 1050 (FIG. 10).

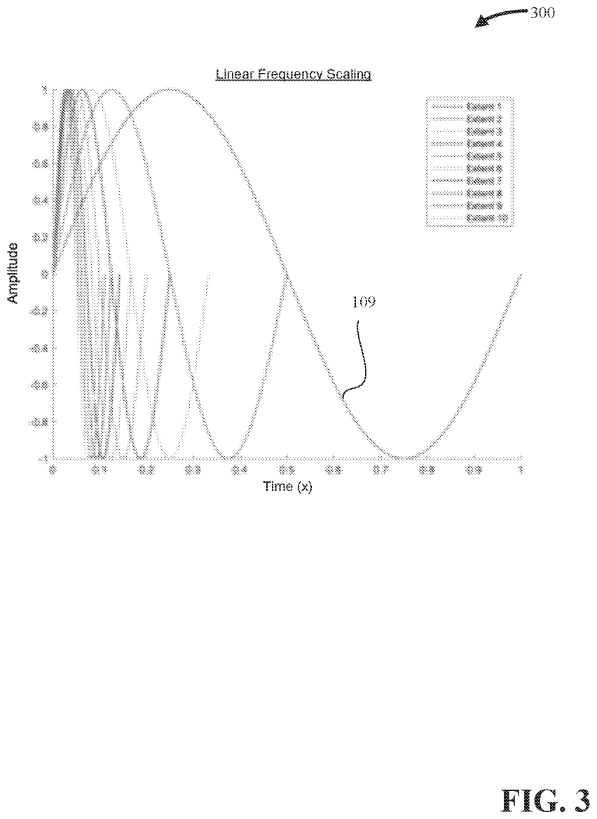

Turning briefly to FIG. 3, and also still to FIG. 2, FIG. 3 illustrates a graph 300 showing the initial waveform 209 as a sinusoid base waveform (extent 1) graphed as a function of amplitude (y-axis) vs. time (x-axis). One or more constants can be applied to the base waveform and/or the respective defining data, and/or the base waveform and/or respective defining data can be stepped through one or more elements in a respective array, to achieve frequency modulation of the base waveform, as represented by the other extents 2-10 also illustrated at graph 300.

The one or more embodiments described herein, such as including the non-limiting system 200, can provide one or more processes for encoding, decoding and/or storage of the base waveform. That is, the process of digital direct synthesis employs a stored base waveform in the form of defining data in memory, which stored waveform can then be manipulated and “stepped through” to produce signals over a desired range of frequencies. Waveform synthesis performed by one or more embodiments described herein, such as by the composing component 212, can enable the base waveform and/or defining data to be stored using much less memory than storage of an actual waveform and/or than existing waveform synthesis techniques.

The composing component 212 generally can perform waveform synthesis to compose the obtained initial waveform 209 and/or initial data 217 into an analog format. This analog format can be a resultant waveform 211, such as an analog waveform, and/or resultant data 219, such as analog data. The composing component 212 generally can perform further waveform synthesis to further compose the analog format, initial waveform 209 and/or the initial data 217 into a running sum index array employing much less memory to store than a waveform and/or a full set of defining data, as will be described below in detail.

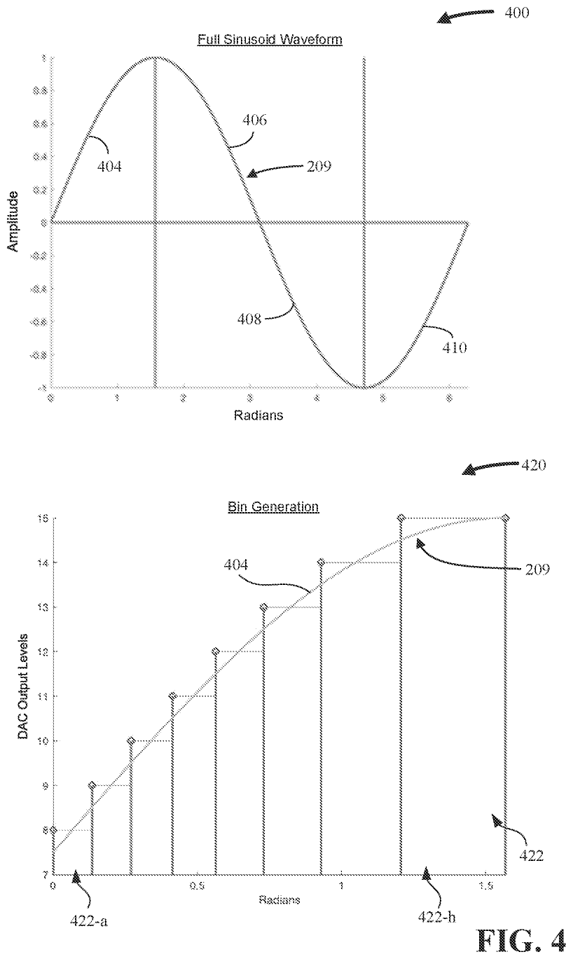

Turning next to FIG. 4, and also still to FIG. 2, the one or more waveform synthesis processes performed by the composing component 212, and thus by the non-limiting system 200, will be further described.

FIG. 4 illustrates another graph of the initial waveform 209. The graph 400 illustrates a full wave period as the initial waveform 209. The initial waveform 209 is a sinusoid waveform graphed as a function of amplitude vs. number of radians. Because the initial waveform 209 has both even and odd symmetry, one quarter of one period of the initial waveform 209 (e.g., a quarter wave of the initial waveform 209) and/or of the initial data 217 therefrom can be composed via the one or more processes to be described below. Indeed, the remaining three quarters of one period of the initial waveform 209 and/or of the initial data 217 therefrom can be generated from a quarter wave encoding.

For example, it will be appreciated that, where possible due to even and/or odd symmetry, the composing component 212, waveform synthesizing system 202, non-limiting system 200 and/or an administrator entity can selectively and/or defaultly determine that a smallest portion (e.g., a quarter of a period) of a waveform and/or data therefrom can be encoded absent encoding of the remaining portion of the waveform and/or data therefrom. In this way, the composing component can provide a compressed output employing a smallest amount of memory for storage of the waveform and/or data therefrom.

Where a waveform being employed by the non-limiting system 200 does not have even and/or odd symmetry, and/or is not periodic, more than a quarter wave of the waveform instead can be encoded. In such case, one or more processes of decoding of the waveform, to be described below, can be unable to be employed, such as the employing of negating and/or reverse playback relative to a quarter wave. In one example, a half of a full period of a waveform can be encoded, such as where even symmetry or odd symmetry only exists within a period, such as with a triangle wave, to thereby reduce the amount of memory to be employed for storing the waveform. In one or more other examples, a full period of a waveform can be encoded where the waveform is periodic but lacks both even and odd symmetry, such as with a sawtooth wave.

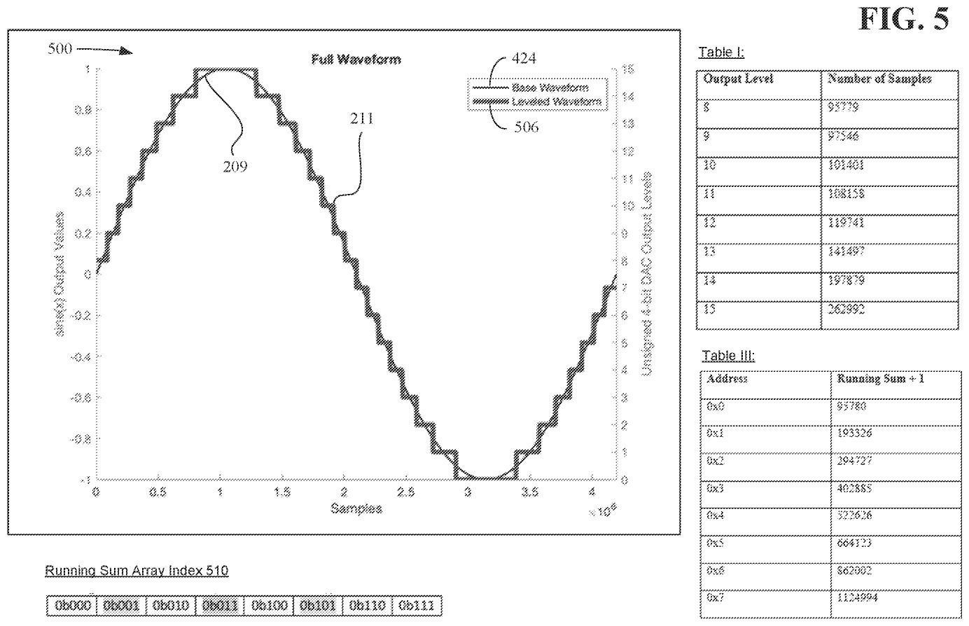

Remaining discussion regarding the waveform synthesizing system 202 will continue with respect to the initial waveform 209 being a sinusoid waveform, and more particularly, with respect to encoding only of the first quarter of the initial waveform 209 and/or of the initial data 217, such as is illustrated at FIG. 5. Nonetheless, it will be appreciated that the remaining discussion also can apply to encoding of other waveforms, and/or of data of another waveform, having other shapes, amplitudes, frequencies and/or symmetries. Such other waveforms can include, but are not limited to, periodic waveforms and/or a waveforms having even and/or odd symmetry.

Accordingly, with respect to a sinusoid initial waveform 209, the composing component 212 and the digital to analog converter component 210 can be employed to compress the initial data 217 defining the initial waveform 209, and indeed to compress initial data 217 defining only a quarter wave of the initial waveform 209, into a format for being stored for decoding at one or more future times.

Referring next still to FIG. 4, and also to FIG. 2, the composing component 212 can first generate a set of resultant data 219 based on initial data 217 defining at least a portion of the first quarter wave 404 of the initial waveform 209. To achieve this generation, the composing component 212 can employ the digital to analog conversion component 210. The initial values (e.g., digital values) representing the first quarter wave 404 of the initial waveform 209 can be sent by the non-limiting system 200 (e.g., by the determination component 208) to the digital to analog conversion component 210 via any suitable communicative method.

The digital to analog conversion component 210 can comprise and/or can employ a digital to analog converter (DAC) to convert the digital values to analog values, and thus to convert the quarter initial waveform 209 (e.g., quarter wave) to a quarter analog waveform 211. The DAC employed can thus be comprised by the non-limiting system 200 and/or disposed external to the non-limiting system 200.

FIG. 4 illustrates a pictorial illustration of the digital to analog conversion of a quarter wave of the initial waveform 209. That is, FIG. 4 illustrates a quarter wave of both the initial waveform 209 and of a converted resultant waveform 211. The resultant waveform 211 is graphed at FIG. 4 as function of DAC output level versus radians, with the initial waveform 209 correspondingly graphed over the analog waveform 211. It will be appreciated that the initial waveform 209 can be defined by a plurality of initial values, such as digital values, of the initial data 217 The one or more initial values can represent one or more points lying along the graphed initial waveform 209. It also will be appreciated that the resultant waveform 211 can be defined by a plurality of resultant values, such as analog values, of the resultant data 219, to be described below in further detail.

It will be appreciated that the waveform synthesis performed by the waveform synthesizing system 202 can be performed with neither generation of a graph of the initial waveform 209 nor of a graph of the converted resultant waveform 211. Indeed, without such graphical and/or pictorial generations, the waveform synthesis performed by the waveform synthesizing system 202 can be faster and/or utilize less memory and/or computer power.

With respect to the digital to analog conversion conducted by the computing component 212 and/or by the digital to analog conversion component 210, a DAC can be employed to at least partially convert initial values of the initial waveform 209 into a string of integers representing a plurality of groups of the initial data 217. More particularly, the DAC can be employed to partition the initial data 217 into a plurality of groups, also referred to herein as bins, with individual groups comprising one or more of the initial values of the initial data 217.

The plurality of groups are partitioned, at least partially, according to the capabilities of the DAC. As illustrated at FIG. 4, a DAC can have one or more output levels. An n-bit DAC generally has 2ⁿ output levels. For example, the DAC employed relative to FIG. 5 is 4-bit and includes sixteen output levels. When encoding a sinusoid wave, such as a high resolution sinusoid wave, multiple initial values, such as digital values, can reside on one or more individual DAC output levels. Additionally, because the first quarter of a sinusoid wave is a monotonically increasing function, successive ones of the DAC levels can be successively reached absent skipping of one or more intermediate DAC levels.

As pictorially represented at FIG. 4, the initial data 217 defining the initial waveform 209 can be at least partially compressed by employing amplitude partitioning of the initial data 217 using equivalent sizing. This amplitude partitioning can be employed to partition the initial data 217 into a plurality of groups of data having equal A amplitudes. That is, a change in amplitude can be the same for the individual groups of the plurality of groups. As used herein, the change of amplitude can be represented by an amplitude of an upper bound for a group minus an amplitude for a lower bound for the group.

In one embodiment, such as illustrated at FIG. 4, the DAC output levels can correspond to midpoints of the groups of the plurality of groups of initial data 217 partitioned. Because the digital data disposed between DAC output levels cannot be directly represented in the DAC analog output, digital data disposed between the DAC output levels can be rounded to the nearest DAC level. What results can be a set of resultant data 219, such as analog data, representing a resultant waveform 211, such as an analog waveform, that corresponds to the initial waveform 209. Furthermore, because the initial waveform 209 is a sinusoid waveform, it will be appreciated that only initial data 217 from a quarter wave of the initial waveform 209 can be converted to analog data 219, absent conversion of initial data 217 from the remaining three quarter waves, to thereby allow a full sinusoid waveform and/or frequency modulations thereof to later be decoded, uncompressed and/or regenerated.

What also results is a time partitioning of the initial data 217 to thereby partition the initial data 217 using varying sizing. This time partitioning can be employed to partition the initial data 217 into a plurality of groups of data having varying A progressing time values that correlate to the equal A amplitudes from the amplitude partitioning. Divisions in the initial data 217 where rounded in opposite directions (e.g., rounded to the nearest DAC output level) can provide dividers for the time partitioning of the initial data 217.

In view of the digital to analog conversion of the initial data 217 defining the initial waveform 209, at individual, such as each of, DAC output levels employed, an analog value, e.g., an integer, can be output. One or more, such as each of the, integers can be a count of a number of values, such as digital values, of the initial data 217 that are partitioned into the plurality of groups of the initial data 217. That is, in view of the equal A amplitude partitioning, and thus varying A time partitioning, one or more individual groups of the plurality of groups of initial data 217 can be separately represented by an individual integer (e.g., one integer per one group). An integer can be the number of counts or initial values of the initial data 217 partitioned at a DAC level.

This is because in view of the equal A amplitude partitioning, and thus varying A time partitioning, the groups of the plurality of groups of initial data 217 can comprise varying counts, e.g., quantities, of the initial values. As used herein, the initial values can be points along the initial waveform 209 and thus define the initial waveform 209. The vector of resultant data that is output, e.g., the vector of integers, can be a successive register of integer quantities of initial values at the one or more DAC output level employed. As will be described below, this vector of resultant data (e.g., analog data) can be further compressed employing run-length encoding and conversion to a running sum array having only binary integers.

First, however, turning still to FIG. 4, the digital to analog conversion performed by the DAC (e.g., by the composing component 212 and/or the digital to analog conversion component 210) is represented pictorially at partial graph 420. As shown, the composing component 212 can compose initial data 217 (e.g., digital data) defining a quarter wave 404 of the periodic initial waveform 209 by employing amplitude partitioning that employs one or more DAC output levels. DAC output levels 7-15 are illustrated in the partial graph 420. The initial data 217 can be partitioned into a plurality of bins 422, such as bin 422a to bin 422h, representing the quarter wave 404 and having equal partitioning of the quarter wave 404 along the y-axis (e.g., amplitude direction) of the quarter wave 404, and also having varying partitioning of the quarter wave 404 along the x-axis (e.g., progressing time direction) of the quarter wave 404. That is, employing the DAC output levels, the plurality of bins 422 can be generated having common bin heights along the y-axis and variable bin widths along the x-axis. Accordingly, one or more, such as each, of the bins 422 can comprise an individual and/or varying quantity of initial values of the quarter wave 404, as represented by an individual integer.

For example, relative to the DAC output level 12, the intersection of the DAC output level 12 with the quarter wave 404 can serve as the midpoint of initial values at that DAC output level 12, with equal partial y-widths below and above the midpoint between DAC output levels. By partitioning equally along the y-axis (e.g., amplitude direction), variable bin size is caused along the x-axis (e.g., progressing time direction).

In view of this partitioning along the y-axis and the x-axis, the shape of a waveform being encoded can direct the bin size employed by the composing component 212 and/or by the digital to analog conversion component 210. That is, different shaped waveforms being encoded can employ the same DAC output levels (e.g., where employing a same digital to analog conversion component 210 or DAC having a same number of output levels), having the same y-axis partitioning, but resulting in a plurality of bins having different variable widths along the x-axis (e.g., resulting in a different vector including the respective successive register of integer quantities of initial values at the one or more DAC output levels employed).

Utilizing the integer quantity at the one or more DAC output levels, in place of a register of the initial values, can employ much less memory. Further, because DAC output levels are successively reached, a vector including the successive register of integers can be directly mapped to the successively increasing DAC output levels for decoding of the vector. That is, a successive order of the bins 422-a to 422-h (see, e.g., FIG. 4) can directly correspond to a register of successively ordered analog output levels of the DAC employed.

After the initial waveform 209 is converted to a resultant waveform 211, into a plurality of bins 422, and further into a vector of successive integers, the vector can be at least temporarily recorded by the waveform synthesizing system 202, such as by the composing component 212 and/or digital to analog conversion component 210. The vector can be recorded at the memory 204 or at any other suitable location internal to or external to the non-limiting system 200 and accessible by the non-limiting system 200.

Looking next to FIG. 5, and also still to FIG. 2, Table I provides an array of the integers and corresponding DAC output levels. That is, as illustrated at Table 1, individual successive DAC output levels (e.g., of the first quarter portion of the initial waveform 209 and resultant waveform 211 illustrated) have associated therewith a number of samples. The number of samples at a DAC output level is an integer representing the number of initial values at a DAC output level. For example, the number of initial values at the DAC output level 12, and thus the integer for the DAC output level 12, is 119741. Together the rows of numbers of samples of Table I can provide the vector of successive integers.

As represented pictorially, graph 500 illustrates the respective output-leveled resultant waveform 211, as converted from the sinusoid initial waveform 209. This graph 500 illustrates the analog waveform 211 graphed as a product of number of samples (e.g., digital values) vs. DAC output levels (y-axis).

Being provided the vector of successive integers, the composing component 212 can employ run-length encoding to provide a run-length encoded array and/or vector of the successive integers. Run-length encoding is a form of data compression where a stream of data is given as an input and a resultant output is a sequence of counts of consecutive data values. Typically, this type of data compression is generally lossless, and as such, when data is decompressed (e.g., decoded), generally all of the initial data will be recovered from the compressed data.

The composing component 212 can comprise a run-length encoding algorithm 213 to provide this run-length encoded array and/or vector. In one or more other embodiments, the run-length encoding algorithm 213 can be stored at the memory 204 or at any other suitable location internal to or external to the non-limiting system 200 and accessible by the composing component 212.

For example, shown below at Table II, a running sum vector (right column) of the integers for the first quarter portion of the initial waveform 209 and the resultant waveform 211 is illustrated, as corresponding to the DAC output level.

TABLE II

| Output | Running Sum |
|---|---|
| Level | of Integers |
| 8 | 95779 |
| 9 | 193325 |
| 10 | 294726 |
| 11 | 402884 |
| 12 | 522625 |
| 13 | 624122 |
| 14 | 862001 |
| 15 | 1124993 |

In one or more additional and/or alternative embodiments, the composing component 212 can compute a running sum +1 array and/or vector. This running sum +1 array and/or vector can be computed from a run-length encoded array and/or vector. Alternatively, this running sum +1 array and/or vector can instead be computed from the vector of successive integers, such as without computing the run-length encoded array and/or vector (non +1) illustrated at Table II.

For example, Table III provides the running sum +1 vector (e.g., for the first quarter of the waveform 424) at the right column of Table III. This right column of Table III can be generated from the right column of Table I (e.g., the vector of successive integers for the first quarter of the waveform 424 illustrated at graph 500) and/or from the right column of Table II. It will be appreciated that the respective Tables I, II and II can be representations that are not actually generated, but rather the values thereof can be represented digitally via one or more arrays, vectors, digital matrices and/or other tensored data.

Next, as illustrated at FIG. 5, a running sum array index 510 can be compiled by the composing component 212, such as employing binary integers representing the running sum +1 vector. As illustrated, the running sum array index 510 at FIG. 5 depicts data from a first quarter of the data at Table III. This limitation can be made for ease of reference, or based on even and/or odd symmetries. Regarding the running sum array index 510, a search value of interest can be compared against the running sum +1 column at Table III, to thereby obtain an address at Table III, which address directly maps to a DAC output level. The conversion works by comparing a search value of interest against Table III's running sum +1 to get a table III address which directly maps to a DAC output level. In one example, it can take log 2(n) comparisons to determine a result, where n is the number of bins (e.g., employing a standard binary search). In this way, as mentioned previously, the vector of analog data 219 (e.g., of the integers) further can be compressed employing run-length encoding and conversion to a running sum array (also referred to herein as a running sum array index) have only binary integers.

The running sum array index 510 can be decoded by the decoding component 214 when the initial waveform 209 is to be regenerated and/or employed, such as for generating one or more signals based on the initial waveform 209 (e.g., such as for being employed in a frequency modulation operation). To achieve the decoding, the decoding component 214 can comprise a binary search algorithm 215 to determine one or more initial values of the initial data 217 of the initial waveform 209, to thereby reproduce the initial data 217 and/or the initial waveform 209. In one or more other embodiments, the binary search algorithm 215 can be stored at the memory 204 or at any other suitable location internal to or external to the non-limiting system 200 and accessible by the composing component 212.

In one example, the binary search algorithm 215 can function by first conducting a most significant bit (msb) comparison. That is, the binary search algorithm 215 can compare a search value with the middle point value on the running sum array vector (e.g., of the running sum array index 510). The search value can be a current sample location for which a DAC output level is being sought. The search value can be determined by a running counter that spans the length of the number of samples in all bins representing the waveform. This counter can count up by variable sized increments (e.g., +1, +10) which can result in different output frequencies since progression through the waveform data can occur at different rates. The counter can be compared against the running sum +1 table (e.g., Table III) to thereby determine in which output level bin the search value resides. The msb-1 point comparison can compare the search value with the lower quarter or upper quarter value on the running sum array vector depending on the result of the previous comparison. This comparison process can continue until a plurality of bits are generated to form a result. The result is an address which corresponds to a bin in the running sum +1 table. This address can then be directly mapped to a DAC output level.

To compute the result, the binary search algorithm 215 and/or the decoding component 214 can employ one or more aspects of hardware (e.g., of the waveform synthesizing system 202). It will be appreciated that the hardware resources employed can be minimal compared to existing waveform decoding approaches. That is, separate comparison vectors can be employed for individual layers to prevent undesired routing during waveform synthesis (e.g., waveform decoding).

For example, there are log 2(n) layers where n is the number of bins. In logic, each layer can be a vector of possible values to compare against. Each vector can be a separate aspect which can enable synthesis by narrowing the scope to only the possible outcomes on each respective layer. Each iteration can have only a single comparison, such as where the previous layer result can determine which index in the next vector to employ. Each comparison layer can produce a 1-bit result starting with the msb going down to the lsb to form the residing bin address result. Each layer bit result can be computed through a comparison expression, such as the decoding component 214 determining if the search value is less than the running sum +1 value. If this is True then that bit position can be determined to be a 0, where otherwise, the bit position can be determined to be a 1. The comparison vectors can be computed by taking the running sum array vector and deconstructing the running sum array vector it into one or more binary tree vectors. The comparison vector layers can be accessible only to a corresponding logic layer that can compute the result of the comparison. As the logic employs the corresponding logic layers, upper to lower bits can be accumulated to reconstruct the resulting bin address which can map to a DAC output level.

Accordingly, at least the initial values of the initial data 217 defining a portion of the initial waveform 209 can be reconstructed from the running sum array index 510. In the present embodiment, where only a quarter wave of the initial waveform 209 and/or of the initial data 217 was encoded, the decoding component 214 can perform generation of the remaining three quarter waves of a period of the initial waveform 209 and/or of the initial data 217. For example, horizontal and/or vertical mirroring of the first quarter wave 404 relative to the other quarters of the initial waveform 209 can allow for negating (e.g., multiplying by −1) and/or reverse playback to be employed to determine one or more additional values (e.g., digital values) of the initial waveform 209 at the second quarter wave 406, third quarter wave 408 and/or fourth quarter wave 410 of one period of the initial waveform 209.

In summary, the initial values of the initial data 217 defining the initial waveform 209 can be reconstructed from a running sum array index employing minimal memory as compared to the memory employed by the plurality of the initial values. Indeed, in one or more embodiments, the amount of resultant data 219 stored can be reduced up to about 99%. The percentage reduction can be represented by Equation 1, provided below.

$${\%}_{reduction} = ( 1 - \frac{{n}_{dac levels}}{{n}_{raw data vαlues}} ) * 100 \qquad Equation 1$$

A signal generation component 216 can be employed to generate one or more signals based on the decoded initial waveform 209 and/or decoded initial data 217, such as employing frequency modulation. With respect to the particular embodiment of FIG. 4, the signal generation component 216 can employ and/or can comprise one or more qubit effectors, such as qubit oscillators, harmonic oscillators, pulse generators and/or the like to cause one or more pulses and/or signals to stimulate and/or manipulate the state(s) of the one or more qubits 207 existing in the quantum system 201. In one or more embodiments, such physical signal generation can be performed by the quantum system 201, such as by the quantum operation component 203. In such case, the signal generation component 216 can provide one or more directions, instructions and/or frequency modulations.

An analysis component 218 can employ one or more aspects of an operating environment, such as the operating environment 900 illustrated at FIG. 9, to provide, such as to receive, retrieve and/or otherwise obtain, one or more experiment results, such as measurement results, from the quantum system 201, such as relative to the one or more qubits 207 operated on. By way of a non-limiting example, the one or more experiment results can be downloaded directly and/or indirectly from the quantum operation component 203 and/or from the waveform synthesizing system 202, received from the memory/storage 952 via the WAN 956 and/or downloaded via the WAN 956 from a node, such as a cloud computing node 1010 of a cloud computing environment 1050 (FIG. 10).

The waveform synthesizing system 202 also can comprise an output component 220. One or more measurement results 226 can be output from the non-limiting system 200 via the output component 220. The one or more measurement results 226 can comprise and/or can be based at least in part on the generation of a signal formed from the initial waveform 209 (e.g., employed as a base waveform), and/or can be responsive to a quantum job request from a requesting entity. For example, the measurement results 226 can comprise one or more oscillating and/or resonant frequencies of one or more of the qubits 207 of the quantum system 201.

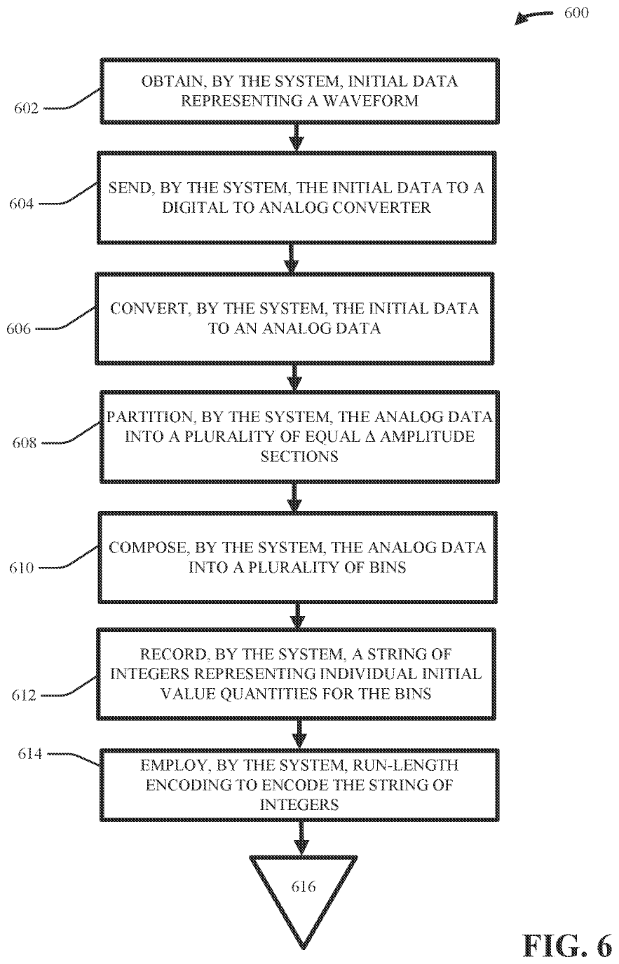

Turning now to FIGS. 6-8, these figures together illustrate a flow diagram of an example, non-limiting computer-implemented method 600 that can facilitate waveform synthesis, in accordance with one or more embodiments described herein with respect to the non-limiting system 200. It will be appreciated that while the computer-implemented method 600 is described relative to the non-limiting system 200, the computer-implemented method 600 can be applicable also to the non-limiting system 100. Repetitive description of like elements and/or processes employed in respective embodiments is omitted for sake of brevity.

Looking first to 602 at FIG. 6, the computer-implemented method 600 can comprise obtaining, by a system (e.g., via determination component 208 of non-limiting system 200 and/or waveform synthesizing system 202) operatively coupled to a processor (e.g., processor 206, a quantum processor and/or like processor) initial data (e.g., initial data 217) representing and/or of a waveform (e.g., initial waveform 209).

At 604, the computer-implemented method 600 can comprise sending, by the system (e.g., via composing component 212 and/or determination component 208), the initial data (e.g., initial data 217) to a DAC (e.g., such as comprised by the digital to analog conversion component 210). It will be appreciated that only a quarter wave or only a half wave of initial values can be employed where suitable.

At 606, the computer-implemented method 600 can comprise converting, by the system (e.g., via composing component 212 and/or digital to analog conversion component 210), the initial data (e.g., initial data 217) to analog data (e.g., the resultant data 219 defining the resultant waveform 211). It will be appreciated that only a quarter wave or only a half wave of initial values can be employed where suitable.

At 608, the computer-implemented method 600 can comprise partitioning, by the system (e.g., via composing component 212 and/or digital to analog conversion component 210), the analog data (e.g., resultant data 219) into a plurality of equal (e.g., common) sections along the amplitude (e.g., y-axis) of the initial waveform (e.g., as illustrated at graph 400).

At 610, the computer-implemented method 600 can comprise composing, by the system (e.g., via composing component 212 and/or digital to analog conversion component 210), the analog data (e.g., resultant data 219) into a plurality of bins (e.g., as represented by the bins 422 including bins 422-a to 422-h at FIG. 4).

At 612, the computer-implemented method 600 can comprise recording, by the system (e.g., via composing component 212), a string of integers representing individual initial value quantities for the bins (e.g., as represented by the right column of Table I at FIG. 5).

At 614, the computer-implemented method 600 can comprise employing, by the system (e.g., via composing component 212), run-length encoding (e.g., via run-length encoding algorithm 213) to encode the string of integers (e.g., as represented by the right column of Table II).

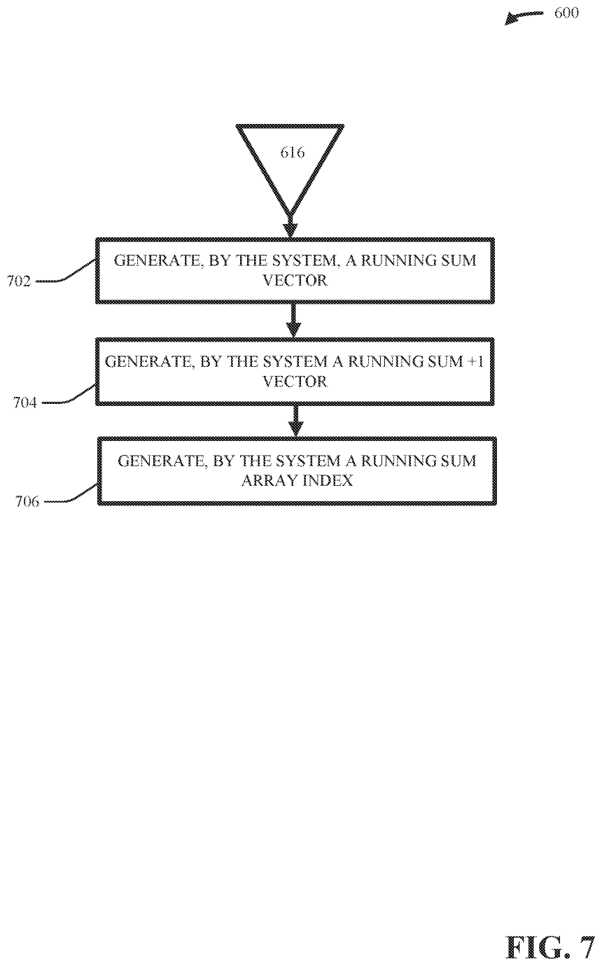

Turning now to FIG. 7, this figure illustrates an extension of the computer-implemented method 600 of FIG. 6, and particularly illustrates aspects that can occur at continuation triangle 616 of FIG. 6.

At 702, the computer-implemented method 600 can continue from the continuation triangle 616 and can comprise generating, by the system (e.g., via run-length encoding algorithm 213), a running sum vector, e.g., based on the run-length encoded string of integers.

At 704, the computer-implemented method 600 can comprise generating, by the system (e.g., via composing component 212 and/or run-length encoding algorithm 213), a running sum +1 vector (e.g., as represented by the right column of Table III at FIG. 5).

At 706, the computer-implemented method 600 can comprise generating, by the system (e.g., via composing component 212 and/or run-length encoding algorithm 213), a running sum array index (e.g., the running sum array index 510 at FIG. 5).

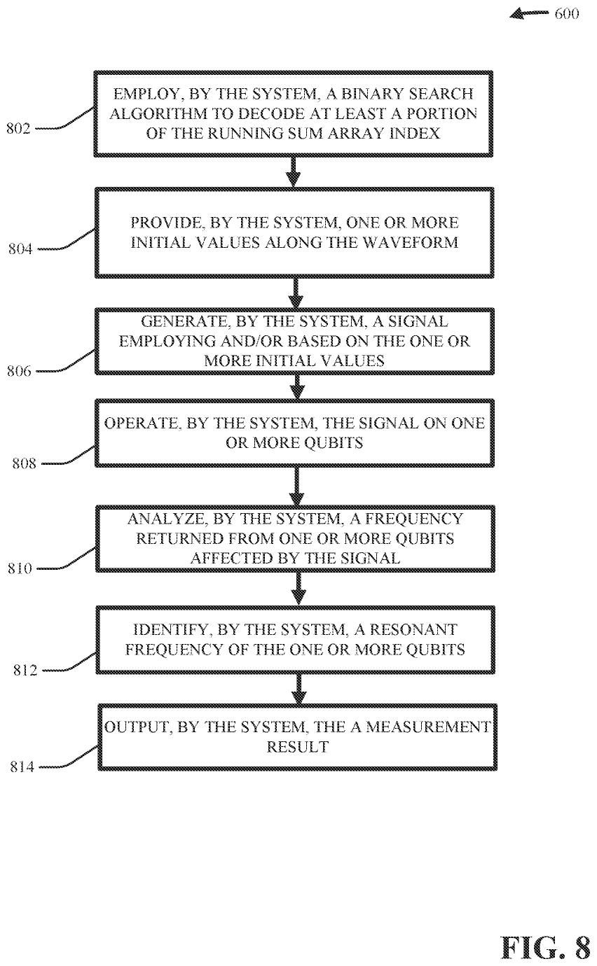

Turning now to FIG. 8, this figure illustrates an extension of the computer-implemented method 600 of FIG. 7 and/or a separate decoding method that can be performed separately, such as at a time at least partially separate from and/or after, the encoding method performed at FIGS. 6 and 7.

At 802, the computer-implemented method 600 can comprise employing, by the system (e.g., via decoding component 214), a binary search algorithm (e.g., binary search algorithm 215) to decode at least a portion of the running sum array index (e.g., the running sum array index 510 at FIG. 5) into one or more DAC output levels and/or one or more initial values of the initial data (e.g., initial data 217).

At 804, the computer-implemented method 600 can comprise providing, by the system (e.g., via decoding component 214) one or more initial values (e.g., of initial data 217) along the regenerated waveform (e.g., a regenerated initial waveform 209).

At 806, the computer-implemented method 600 can comprise generating, by the system (e.g., via signal generation component 216 and/or quantum operation component 203), a signal employing and/or based on the one or more initial values.

At 808, the computer-implemented method 600 can comprise operating, by the system (e.g., via signal generation component 216 and/or quantum operation component 203), the signal on one or more qubits (e.g., qubits 207).

At 810, the computer-implemented method 600 can comprise analyzing, by the system (e.g., via analysis component 218 and/or quantum operation component 203), a frequency returned from one or more qubits (e.g., qubits 207) affected by the signal.

At 812, the computer-implemented method 600 can comprise identifying, by the system (e.g., via analysis component 218 and/or quantum operation component 203), a resonant frequency of the one or more qubits (e.g., qubits 207).

At 814, the computer-implemented method 600 can comprise outputting, by the system (e.g., via output component 220) one or more measurement results (e.g., one or more measurement results 226).

For simplicity of explanation, the computer-implemented methodologies provided herein are depicted and/or described as a series of acts. It is to be understood and appreciated that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented methodologies in accordance with the described subject matter. In addition, those skilled in the art will understand and appreciate that the computer-implemented methodologies could alternatively be represented as a series of interrelated states via a state diagram or events. Additionally, it should be further appreciated that the computer-implemented methodologies described hereinafter and throughout this specification are capable of being stored on an article of manufacture to facilitate transporting and transferring the computer-implemented methodologies to computers. The term article of manufacture, as used herein, is intended to encompass a computer program accessible from any computer-readable device or storage media.

Turning now to the FIGS. 4-11 in combination, and still to the non-limiting system 200 and waveform synthesizing system 202, one or more embodiments as described herein can provide a new approach driven by previously unincorporated A amplitude partitioning of at least a portion of a waveform, such as relative to one or more employed DAC output levels. For example, waveform synthesizing system 202 and/or non-limiting system 200 can provide a high-fidelity signal as compared to existing approaches for signal generation. The waveform synthesizing system 202 can process, such as synthesize, waveforms having variable shapes, amplitudes, frequencies and/or symmetries, and/or further can enable faster synthesis relative to periodic waveforms and/or waveforms having even and/or odd symmetry.

Waveform synthesizing system 202 and/or non-limiting system 200 can provide technical improvements to one or more systems employing the waveform synthesizing system 202. One technical improvement can include the ability to regenerate a waveform more quickly and/or to regenerate a high quality and/or high-fidelity waveform as compared to use of a lookup table. These technical improvements can be achieved in part due to the employment by the waveform synthesis approach of the waveform synthesizing system 202 and/or non-limiting system 200 of less memory, less time and/or less computing power than existing waveform synthesis approaches.

Additionally and/or alternatively, another technical improvement can be such employment and or utilization of less memory, less time, and/or less computing power than existing waveform synthesis approaches. Indeed, an advantage of the one or more process to be performed by the waveform synthesizing system 202 can be an enhanced (e.g., improved and/or optimized) execution of a waveform regeneration, such as comprising a direct reduction in memory employed, in time taken and/or in power used to perform the respective waveform synthesis (e.g., regeneration and/or decoding).

Accordingly, the described subject matter, by employing the composing component 212, decoding component 214 and/or waveform synthesizing system 202, can create an improvement in speed of execution of jobs due to the use of less memory, less time and/or less computing power. For example, relative to a hybrid classical/quantum non-limiting system 200, where there can be a high demand for execution of a large quantity of quantum programs employing the quantum system 201, it can follow that use of the non-limiting system 200 (e.g., including the waveform synthesizing system 202, composing component 212 and/or decoding component 214) can facilitate scaled execution of quantum programs via scaled execution of associated waveform synthesis (e.g., waveform and/or data encoding and/or decoding).

Moreover, by reducing time, processing power and/or memory utilized and/or incurred during performance of one or more quantum programs (e.g., during one or more measurements regarding one or more qubits), slower occurrence of decoherence of the one or more qubits employed can occur. Slower decoherence can allow for additional quantum programs to be executed on the qubits. This in turn can lead to a related reduction in provision of new qubits by a quantum system comprising the one or more qubits, and consequently, increased availability of processing capabilities of a quantum processor of a quantum system due, at least in part, to the decreased provision of new qubits.

A practical application of the waveform synthesizing system 202 and/or non-limiting system 200 is that it can be implemented in one or more domains to enable scaled waveform synthesis. For example, the waveform synthesizing system 202 can quickly and/or automatically encode data (e.g., digital values) from an initial waveform 209 (e.g., a digital waveform) having a variety of shapes, amplitudes, frequencies and/or symmetries. Further, use of the waveform synthesizing system 202 itself can be scalable, such as where the waveform synthesizing system 202 can perform at least one waveform synthesis at least partially in parallel at a same time with another waveform synthesis.

Moreover, one or more embodiments described herein can control real-world devices based on the disclosed teachings. For example, one or more embodiments described herein can provide waveform synthesis of relative to a waveform, and/or digital data representing a waveform, provided by a real-world classical and/or quantum device, such as for operation of one or more programs and/or experiments to be operated on one or more real-world qubits.

While the one or more advantages described above have been described with reference to FIGS. 4-11 and the non-limiting system 200, it will be appreciated that one or more of the advantages described above also can be applicable to the non-limiting system 100.

Description now turns to that applicable to one or more embodiments as described above with respect to FIGS. 1-11, with respect to one or more of non-limiting systems 100 and/or 200, and/or with respect to extensions and/or modifications thereof. The systems and/or devices have been (and/or will be further) described herein with respect to interaction between one or more components. It should be appreciated that such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

It is to be appreciated that one or more embodiments described herein are inherently and/or inextricably tied to computer technology and cannot be implemented outside of a hybrid classical/quantum computing environment. For example, one or more processes performed by one or more embodiments described herein can more efficiently, and even more feasibly, provide waveform synthesis as compared to current systems and/or techniques. Systems, computer-implemented methods and/or computer program products facilitating performance of these processes are of great utility in the field of quantum computation and cannot be equally practicably implemented in a sensible way outside of a computing environment.

It also is to be appreciated that one or more embodiments described herein can employ hardware and/or software to solve problems that are highly technical in nature (e.g., related to digital to analog conversion and/or binary searching of a plurality of data), that are not abstract, and that cannot be performed as a set of mental acts by a human. For example, a human, or even thousands of humans, cannot efficiently, accurately and/or effectively compute digital to analog conversions and/or binary searching of a plurality of data in the time that one or more embodiments described herein can facilitate this process. And, neither the human mind nor a human with pen and paper electronically compute digital to analog conversions and/or binary searching of a plurality of data as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing the one or more operations described herein.

Turning next to FIG. 9-11, to provide additional context for one or more embodiments described herein at FIGS. 1-8, FIGS. 9-11 are described in detail.

FIG. 9 and the following discussion are intended to provide a brief, general description of a suitable operating environment 900 in which one or more embodiments described herein at FIGS. 1-8 can be implemented. For example, one or more components and/or other aspects of embodiments described herein can be implemented in or be associated with, such as accessible via, the operating environment 900. Further, while one or more embodiments have been described above in the general context of computer-executable instructions that can run on one or more computers, those skilled in the art will recognize that one or more embodiments also can be implemented in combination with other program modules and/or as a combination of hardware and software.

Generally, program modules include routines, programs, components, data structures and/or the like, that perform particular tasks and/or implement particular abstract data types. Moreover, those skilled in the art will appreciate that the inventive methods can be practiced with other computer system configurations, including single-processor or multiprocessor computer systems, minicomputers, mainframe computers, Internet of Things (IoT) devices, distributed computing systems, as well as personal computers, hand-held computing devices, microprocessor-based or programmable consumer electronics, and/or the like, each of which can be operatively coupled to one or more associated devices.

Computing devices typically include a variety of media, which can include computer-readable storage media, machine-readable storage media and/or communications media, which two terms are used herein differently from one another as follows. Computer-readable storage media or machine-readable storage media can be any available storage media that can be accessed by the computer and includes both volatile and nonvolatile media, removable and non-removable media. By way of example, but not limitation, computer-readable storage media and/or machine-readable storage media can be implemented in connection with any method or technology for storage of information such as computer-readable and/or machine-readable instructions, program modules, structured data and/or unstructured data.

Computer-readable storage media can include, but are not limited to, random access memory (RAM), read only memory (ROM), electrically erasable programmable read only memory (EEPROM), flash memory or other memory technology, compact disk read only memory (CD ROM), digital versatile disk (DVD), Blu-ray disc (BD) and/or other optical disk storage, magnetic cassettes, magnetic tape, magnetic disk storage and/or other magnetic storage devices, solid state drives or other solid state storage devices and/or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory and/or computer-readable media that are not only propagating transitory signals per se.

Computer-readable storage media can be accessed by one or more local or remote computing devices, e.g., via access requests, queries and/or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, but not limitation, communication media can include wired media, such as a wired network, direct-wired connection and/or wireless media such as acoustic, RF, infrared and/or other wireless media.

With reference again to FIG. 9, the example operating environment 900 for implementing one or more embodiments of the aspects described herein can include a computer 902, the computer 902 including a processing unit 906, a system memory 904 and/or a system bus 908. It will be appreciated that one or more aspects of the system memory 904 or processing unit 906 can be applied to memories 104 and/or 204 and/or to processors 106 and/or 206, respectively of the non-limiting systems 100 and/or 200. It also will be appreciated that the system memory 904 can be implemented in combination with and/or alternatively to memories 104 and/or 204. Likewise, it also will be appreciated that the processing unit 906 can be implemented in combination with and/or alternatively to processors 106 and/or 206.

Memory 904 can store one or more computer and/or machine readable, writable and/or executable components and/or instructions that, when executed by processing unit 906 (e.g., a classical processor, a quantum processor and/or like processor), can facilitate performance of operations defined by the executable component(s) and/or instruction(s). For example, memory 904 can store computer and/or machine readable, writable and/or executable components and/or instructions that, when executed by processing unit 906, can facilitate execution of the one or more functions described herein relating to non-limiting systems 100 and/or 200 and/or waveform synthesis systems 102 and/or 202, as described herein with or without reference to the one or more figures of the one or more embodiments.

Memory 904 can comprise volatile memory (e.g., random access memory (RAM), static RAM (SRAM), dynamic RAM (DRAM) and/or the like) and/or non-volatile memory (e.g., read only memory (ROM), programmable ROM (PROM), electrically programmable ROM (EPROM), electrically erasable programmable ROM (EEPROM) and/or the like) that can employ one or more memory architectures.

Processing unit 906 can comprise one or more types of processors and/or electronic circuitry (e.g., a classical processor, a quantum processor and/or like processor) that can implement one or more computer and/or machine readable, writable and/or executable components and/or instructions that can be stored at memory 904. For example, processing unit 906 can perform one or more operations that can be specified by computer and/or machine readable, writable and/or executable components and/or instructions including, but not limited to, logic, control, input/output (I/O), arithmetic and/or the like. In one or more embodiments, processing unit 906 can be any of one or more commercially available processors. In one or more embodiments, processing unit 906 can comprise one or more central processing unit, multi-core processor, microprocessor, dual microprocessors, microcontroller, System on a Chip (SOC), array processor, vector processor, quantum processor and/or another type of processor. The examples of processing unit 906 can be employed to implement one or more embodiments described herein.

The system bus 908 can couple system components including, but not limited to, the system memory 904 to the processing unit 906. The system bus 908 can comprise one or more types of bus structure that can further interconnect to a memory bus (with or without a memory controller), a peripheral bus and/or a local bus using one or more of a variety of commercially available bus architectures. The system memory 904 can include ROM 910 and/or RAM 912. A basic input/output system (BIOS) can be stored in a non-volatile memory such as ROM, erasable programmable read only memory (EPROM) and/or EEPROM, which BIOS contains the basic routines that help to transfer information among elements within the computer 902, such as during startup. The RAM 912 can include a high-speed RAM, such as static RAM for caching data.

The computer 902 can include an internal hard disk drive (HDD) 914 (e.g., EIDE, SATA), one or more external storage devices 916 (e.g., a magnetic floppy disk drive (FDD), a memory stick or flash drive reader, a memory card reader and/or the like) and/or a drive 920, e.g., such as a solid state drive or an optical disk drive, which can read or write from a disk 922, such as a CD-ROM disc, a DVD, a BD and/or the like. Additionally and/or alternatively, where a solid state drive is involved, disk 922 could not be included, unless separate. While the internal HDD 914 is illustrated as located within the computer 902, the internal HDD 914 can also be configured for external use in a suitable chassis (not shown). Additionally, while not shown in operating environment 900, a solid state drive (SSD) can be used in addition to, or in place of, an HDD 914. The HDD 914, external storage device(s) 916 and drive 920 can be connected to the system bus 908 by an HDD interface 924, an external storage interface 926 and a drive interface 928, respectively. The HDD interface 924 for external drive implementations can include at least one or both of Universal Serial Bus (USB) and Institute of Electrical and Electronics Engineers (IEEE) 1394 interface technologies. Other external drive connection technologies are within contemplation of the embodiments described herein.

The drives and their associated computer-readable storage media provide nonvolatile storage of data, data structures, computer-executable instructions, and so forth. For the computer 902, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, can also be used in the example operating environment, and/or that any such storage media can contain computer-executable instructions for performing the methods described herein.

A number of program modules can be stored in the drives and RAM 912, including an operating system 930, one or more applications 932, other program modules 934 and/or program data 936. All or portions of the operating system, applications, modules and/or data can also be cached in the RAM 912. The systems and/or methods described herein can be implemented utilizing one or more commercially available operating systems and/or combinations of operating systems.

Computer 902 can optionally comprise emulation technologies. For example, a hypervisor (not shown) or other intermediary can emulate a hardware environment for operating system 930, and the emulated hardware can optionally be different from the hardware illustrated in FIG. 9. In a related embodiment, operating system 930 can comprise one virtual machine (VM) of multiple VMs hosted at computer 902. Furthermore, operating system 930 can provide runtime environments, such as the JAVA runtime environment or the .NET framework, for applications 932. Runtime environments are consistent execution environments that can allow applications 932 to run on any operating system that includes the runtime environment. Similarly, operating system 930 can support containers, and applications 932 can be in the form of containers, which are lightweight, standalone, executable packages of software that include, e.g., code, runtime, system tools, system libraries and/or settings for an application.

Further, computer 902 can be enabled with a security module, such as a trusted processing module (TPM). For instance, with a TPM, boot components hash next in time boot components and wait for a match of results to secured values before loading a next boot component. This process can take place at any layer in the code execution stack of computer 902, e.g., applied at application execution level and/or at operating system (OS) kernel level, thereby enabling security at any level of code execution.

An entity can enter and/or transmit commands and/or information into the computer 902 through one or more wired/wireless input devices, e.g., a keyboard 938, a touch screen 940 and/or a pointing device, such as a mouse 942. Other input devices (not shown) can include a microphone, an infrared (IR) remote control, a radio frequency (RF) remote control and/or other remote control, a joystick, a virtual reality controller and/or virtual reality headset, a game pad, a stylus pen, an image input device, e.g., camera(s), a gesture sensor input device, a vision movement sensor input device, an emotion or facial detection device, a biometric input device, e.g., fingerprint and/or iris scanner, and/or the like. These and other input devices can be connected to the processing unit 906 through an input device interface 944 that can be coupled to the system bus 908, but can be connected by other interfaces, such as a parallel port, an IEEE 1394 serial port, a game port, a USB port, an IR interface, a BLUETOOTH® interface and/or the like.

A monitor 946 or other type of display device can be alternatively and/or additionally connected to the system bus 908 via an interface, such as a video adapter 948. In addition to the monitor 946, a computer typically includes other peripheral output devices (not shown), such as speakers, printers and/or the like.

The computer 902 can operate in a networked environment using logical connections via wired and/or wireless communications to one or more remote computers, such as a remote computer(s) 950. The remote computer(s) 950 can be a workstation, a server computer, a router, a personal computer, portable computer, microprocessor-based entertainment appliance, a peer device and/or other common network node, and typically includes many or all of the elements described relative to the computer 902, although, for purposes of brevity, only a memory/storage device 952 is illustrated. Additionally and/or alternatively, the computer 902 can be coupled (e.g., communicatively, electrically, operatively, optically and/or the like) to one or more external systems, sources and/or devices (e.g., classical and/or quantum computing devices, communication devices and/or like device) via a data cable (e.g., High-Definition Multimedia Interface (HDMI), recommended standard (RS) 232, Ethernet cable and/or the like).

In one or more embodiments, a network can comprise one or more wired and/or wireless networks, including, but not limited to, a cellular network, a wide area network (WAN) (e.g., the Internet), or a local area network (LAN). For example, one or more embodiments described herein can communicate with one or more external systems, sources and/or devices, for instance, computing devices (and vice versa) using virtually any desired wired or wireless technology, including but not limited to: wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (IPv6 over Low power Wireless Area Networks), Z-Wave, an ANT, an ultra-wideband (UWB) standard protocol and/or other proprietary and/or non-proprietary communication protocols. In a related example, one or more embodiments described herein can include hardware (e.g., a central processing unit (CPU), a transceiver, a decoder, quantum hardware, a quantum processor and/or the like), software (e.g., a set of threads, a set of processes, software in execution, quantum pulse schedule, quantum circuit, quantum gates and/or the like) and/or a combination of hardware and/or software that facilitates communicating information among one or more embodiments described herein and external systems, sources and/or devices (e.g., computing devices, communication devices and/or the like).

The logical connections depicted include wired/wireless connectivity to a local area network (LAN) 954 and/or larger networks, e.g., a wide area network (WAN) 956. LAN and WAN networking environments can be commonplace in offices and companies and can facilitate enterprise-wide computer networks, such as intranets, all of which can connect to a global communications network, e.g., the Internet.

When used in a LAN networking environment, the computer 902 can be connected to the local network 954 through a wired and/or wireless communication network interface or adapter 958. The adapter 958 can facilitate wired and/or wireless communication to the LAN 954, which can also include a wireless access point (AP) disposed thereon for communicating with the adapter 958 in a wireless mode.

When used in a WAN networking environment, the computer 902 can include a modem 960 and/or can be connected to a communications server on the WAN 956 via other means for establishing communications over the WAN 956, such as by way of the Internet. The modem 960, which can be internal and/or external and a wired and/or wireless device, can be connected to the system bus 908 via the input device interface 944. In a networked environment, program modules depicted relative to the computer 902 or portions thereof can be stored in the remote memory/storage device 952. It will be appreciated that the network connections shown are merely exemplary and one or more other means of establishing a communications link among the computers can be used.

When used in either a LAN or WAN networking environment, the computer 902 can access cloud storage systems or other network-based storage systems in addition to, and/or in place of, external storage devices 916 as described above, such as but not limited to, a network virtual machine providing one or more aspects of storage and/or processing of information. Generally, a connection between the computer 902 and a cloud storage system can be established over a LAN 954 or WAN 956 e.g., by the adapter 958 or modem 960, respectively. Upon connecting the computer 902 to an associated cloud storage system, the external storage interface 926 can, such as with the aid of the adapter 958 and/or modem 960, manage storage provided by the cloud storage system as it would other types of external storage. For instance, the external storage interface 926 can be configured to provide access to cloud storage sources as if those sources were physically connected to the computer 902.

The computer 902 can be operable to communicate with any wireless devices and/or entities operatively disposed in wireless communication, e.g., a printer, scanner, desktop and/or portable computer, portable data assistant, communications satellite, telephone and/or any piece of equipment or location associated with a wirelessly detectable tag (e.g., a kiosk, news stand, store shelf and/or the like). This can include Wireless Fidelity (Wi-Fi) and BLUETOOTH® wireless technologies. Thus, the communication can be a predefined structure as with a conventional network or simply an ad hoc communication between at least two devices.

The illustrated embodiments described herein can be practiced in distributed computing environments (e.g., cloud computing environments), such as described below with respect to FIG. 10, where certain tasks are performed by remote processing devices that are linked through a communications network. In a distributed computing environment, program modules can be located both in local and/or remote memory storage devices.

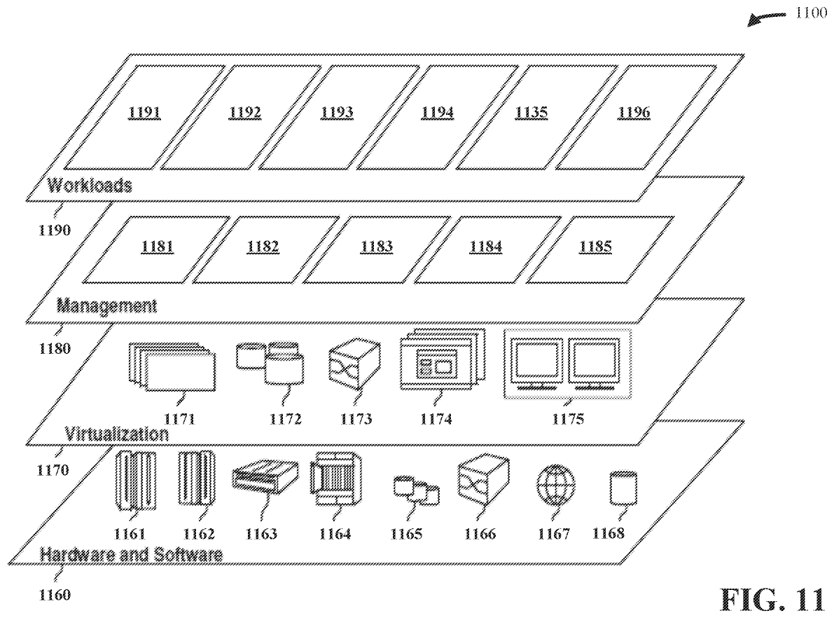

For example, one or more embodiments described herein and/or one or more components thereof can employ one or more computing resources of the cloud computing environment 1050 described below with reference to FIG. 10, and/or with reference to the one or more functional abstraction layers (e.g., quantum software and/or the like) described below with reference to FIG. 11, to execute one or more operations in accordance with one or more embodiments described herein. For example, cloud computing environment 1050 and/or one or more of the functional abstraction layers 1160, 1170, 1180 and/or 1190 can comprise one or more classical computing devices (e.g., classical computer, classical processor, virtual machine, server and/or the like), quantum hardware and/or quantum software (e.g., quantum computing device, quantum computer, quantum processor, quantum circuit simulation software, superconducting circuit and/or the like) that can be employed by one or more embodiments described herein and/or components thereof to execute one or more operations in accordance with one or more embodiments described herein. For instance, one or more embodiments described herein and/or components thereof can employ such one or more classical and/or quantum computing resources to execute one or more classical and/or quantum: mathematical function, calculation and/or equation; computing and/or processing script; algorithm; model (e.g., artificial intelligence (AI) model, machine learning (ML) model and/or like model); and/or other operation in accordance with one or more embodiments described herein.

It is to be understood that although one or more embodiments described herein include a detailed description on cloud computing, implementation of the teachings recited herein are not limited to a cloud computing environment. Rather, one or more embodiments described herein are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines and services) that can be rapidly provisioned and released with minimal management effort or interaction with a provider of the service. This cloud model can include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand There is a sense of location independence in that the consumer generally has no control or knowledge over the exact location of the provided resources but can specify location at a higher level of abstraction (e.g., country, state and/or datacenter).

Rapid elasticity: capabilities can be rapidly and elastically provisioned, in one or more cases automatically, to quickly scale out and rapidly released to quickly scale in. To the consumer, the capabilities available for provisioning can appear to be unlimited and can be purchased in any quantity at any time.

Measured service: cloud systems automatically control and optimize resource use by leveraging a metering capability at one or more levels of abstraction appropriate to the type of service (e.g., storage, processing, bandwidth and/or active user accounts). Resource usage can be monitored, controlled and/or reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage and/or individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems and/or storage, but has control over the deployed applications and possibly application hosting environment configurations.

Infrastructure as a Service (IaaS): the capability provided to the consumer is to provision processing, storage, networks and/or other fundamental computing resources where the consumer can deploy and run arbitrary software, which can include operating systems and applications. The consumer does not manage or control the underlying cloud infrastructure but has control over operating systems, storage, deployed applications and/or possibly limited control of select networking components (e.g., host firewalls).

Deployment Models are as follows:

Private cloud: the cloud infrastructure is operated solely for an organization. It can be managed by the organization or a third party and can exist on-premises or off-premises.

Community cloud: the cloud infrastructure is shared by several organizations and supports a specific community that has shared concerns (e.g., mission, security requirements, policy and/or compliance considerations). It can be managed by the organizations or a third party and can exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community or public) that remain unique entities but are bound together by standardized or proprietary technology that enables data and application portability (e.g., cloud bursting for load-balancing among clouds).

A cloud computing environment is service oriented with a focus on statelessness, low coupling, modularity and/or semantic interoperability. At the heart of cloud computing is an infrastructure that includes a network of interconnected nodes.

Moreover, the non-limiting systems 100 and/or 200 and/or the example operating environment 900 can be associated with and/or be included in a data analytics system, a data processing system, a graph analytics system, a graph processing system, a big data system, a social network system, a speech recognition system, an image recognition system, a graphical modeling system, a bioinformatics system, a data compression system, an artificial intelligence system, an authentication system, a syntactic pattern recognition system, a medical system, a health monitoring system, a network system, a computer network system, a communication system, a router system, a server system, a high availability server system (e.g., a Telecom server system), a Web server system, a file server system, a data server system, a disk array system, a powered insertion board system, a cloud-based system and/or the like. In accordance therewith, non-limiting systems 100 and/or 200 and/or example operating environment 900 can be employed to use hardware and/or software to solve problems that are highly technical in nature, that are not abstract and/or that cannot be performed as a set of mental acts by a human.

Referring now to details of one or more aspects illustrated at FIG. 10, the illustrative cloud computing environment 1050 is depicted. As shown, cloud computing environment 1050 includes one or more cloud computing nodes 1010 with which local computing devices used by cloud consumers, such as, for example, personal digital assistant (PDA) or cellular telephone 1054A, desktop computer 1054B, laptop computer 1054C and/or automobile computer system 1054N can communicate. Although not illustrated in FIG. 10, cloud computing nodes 1010 can further comprise a quantum platform (e.g., quantum computer, quantum hardware, quantum software and/or the like) with which local computing devices used by cloud consumers can communicate. Cloud computing nodes 1010 can communicate with one another. They can be grouped (not shown) physically or virtually, in one or more networks, such as Private, Community, Public, or Hybrid clouds as described hereinabove, or a combination thereof. This allows cloud computing environment 1050 to offer infrastructure, platforms and/or software as services for which a cloud consumer does not need to maintain resources on a local computing device. It is understood that the types of computing devices 1054A-N shown in FIG. 10 are intended to be illustrative only and that cloud computing nodes 1010 and cloud computing environment 1050 can communicate with any type of computerized device over any type of network and/or network addressable connection (e.g., using a web browser).

Referring now to details of one or more aspects illustrated at FIG. 11, a set 1100 of functional abstraction layers is shown, such as provided by cloud computing environment 1050 (FIG. 10). One or more embodiments described herein can be associated with, such as accessible via, one or more functional abstraction layers described below with reference to FIG. 11 (e.g., hardware and software layer 1160, virtualization layer 1170, management layer 1180 and/or workloads layer 1190). It should be understood in advance that the components, layers and/or functions shown in FIG. 11 are intended to be illustrative only and embodiments described herein are not limited thereto. As depicted, the following layers and/or corresponding functions are provided:

Hardware and software layer 1160 can include hardware and software components. Examples of hardware components include: mainframes 1161; RISC (Reduced Instruction Set Computer) architecture-based servers 1162; servers 1163; blade servers 1164; storage devices 1165; and/or networks and/or networking components 1166. In one or more embodiments, software components can include network application server software 1167, quantum platform routing software 1168; and/or quantum software (not illustrated in FIG. 11).

Virtualization layer 1170 can provide an abstraction layer from which the following examples of virtual entities can be provided: virtual servers 1171; virtual storage 1172; virtual networks 1173, including virtual private networks; virtual applications and/or operating systems 1174; and/or virtual clients 1175.

In one example, management layer 1180 can provide the functions described below. Resource provisioning 1181 can provide dynamic procurement of computing resources and other resources that can be utilized to perform tasks within the cloud computing environment. Metering and Pricing 1182 can provide cost tracking as resources are utilized within the cloud computing environment, and/or billing and/or invoicing for consumption of these resources. In one example, these resources can include one or more application software licenses. Security can provide identity verification for cloud consumers and/or tasks, as well as protection for data and/or other resources. User (or entity) portal 1183 can provide access to the cloud computing environment for consumers and system administrators. Service level management 1184 can provide cloud computing resource allocation and/or management such that required service levels are met. Service Level Agreement (SLA) planning and fulfillment 1185 can provide pre-arrangement for, and procurement of, cloud computing resources for which a future requirement is anticipated in accordance with an SLA.

Workloads layer 1190 can provide examples of functionality for which the cloud computing environment can be utilized. Non-limiting examples of workloads and functions which can be provided from this layer include: mapping and navigation 1191; software development and lifecycle management 1192; virtual classroom education delivery 1193; data analytics processing 1194; transaction processing 1195; and/or application transformation software 1196.

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a semiconductor storage device and/or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function(s). In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented in combination with one or more other program modules. Generally, program modules include routines, programs, components, data structures and/or the like that perform particular tasks and/or implement particular abstract data types. Moreover, those skilled in the art will appreciate that the inventive computer-implemented methods can be practiced with other computer system configurations, including single-processor and/or multiprocessor computer systems, mini-computing devices, mainframe computers, as well as computers, hand-held computing devices (e.g., PDA, phone), microprocessor-based or programmable consumer and/or industrial electronics and/or the like. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform,” “interface,” and/or the like, can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim.

The descriptions of the one or more embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor that executes the computer executable components stored in the memory, wherein the computer executable components comprise:
a composing component that compresses data defining a waveform by employing amplitude partitioning of the data using equivalent sizing.

2. The system of claim 1,
wherein the composing component further partitions the data employing time partitioning of the data using varying sizing.

3. The system of claim 1,
wherein a plurality of groups of the data partitioned by the composing component define successively progressing, time partitioned sections of the data.

4. The system of claim 1,
wherein the composing component further employs run-length encoding to generate a string of integers representing a plurality of groups of the data as partitioned according both to amplitude and progressing time.

5. The system of claim 4,
wherein the integers comprise a running sum of individual quantities of values of the data that are partitioned into the plurality of groups of the data.

6. The system of claim 1,
wherein a successive order of a plurality of groups of the data, as partitioned according both to amplitude and progressing time, directly corresponds to a register of successively increasing analog output levels of a digital to analog converter.

7. The system of claim 1, further comprising:
a decoding component that employs a binary search to decode a running sum array of integers representing at least a portion of the data, to decompress the data.

8. A computer-implemented method, comprising:
compressing, by a system operatively coupled to a processor, data defining a waveform by employing amplitude partitioning of the data using equivalent sizing.

9. The computer-implemented method of claim 8, further comprising:
partitioning, by the system, the data employing time partitioning of the data using varying sizing.

10. The computer-implemented method of claim 8,
wherein a plurality of groups of the data partitioned by the composing component define successively progressing, time partitioned sections of the data.

11. The computer-implemented method of claim 8, further comprising:
employing, by the system, run-length encoding to generate a string of integers representing a plurality of groups of the data as partitioned according both to amplitude and progressing time.

12. The computer-implemented method of claim 11,
wherein the integers comprise a running sum of individual quantities of values of the data that are partitioned into the plurality of groups of the data.

13. The computer-implemented method of claim 8,
wherein a successive order of a plurality of groups of the data, as partitioned according both to amplitude and progressing time, directly corresponds to a register of successively increasing analog output levels of a digital to analog converter.

14. The computer-implemented method of claim 8, further comprising:
employing, by the system, a binary search to decode a running sum array of integers representing at least a portion of the data, to decompress the data.

15. A computer program product facilitating a process to synthesize a waveform, the computer program product comprising a computer readable storage medium having program instructions embodied therewith, the program instructions executable by a processor to cause the processor to:
compress, by the processor, data defining a waveform by employing amplitude partitioning of the data using equivalent sizing.

16. The computer program product of claim 15, wherein the program instructions are further executable by the processor to cause the processor to:
partition, by the processor, the data employing time partitioning of the data using varying sizing.

17. The computer program product of claim 15,
wherein a plurality of groups of the data partitioned by the composing component define successively progressing, time partitioned sections of the data.

18. The computer program product of claim 15, wherein the program instructions are further executable by the processor to cause the processor to:
employ, by the processor, run-length encoding to generate a string of integers representing a plurality of groups of the data as partitioned according both to amplitude and progressing time.

19. The computer program product of claim 18,
wherein the integers comprise a running sum of individual quantities of values of the data that are partitioned into the plurality of groups of the data.

20. The computer program product of claim 15, wherein the program instructions are further executable by the processor to cause the processor to:
employ, by the processor, a binary search to decode a running sum array of integers representing at least a portion of the data, to decompress the data.
